(19) United States
(12) Patent Application Publication
(10) Pub. No.: US 2010/0226110 A1
(43) Pub. Date: Sep. 9, 2010

(54) Printed wiring board, printed IC board having the printed wiring board, and method of manufacturing the same

(75) Inventor: Takuya Kouya, Nagoya (JP)

Correspondence Address: HARNESS, DICKEY & PIERCE, P.L.C., P.O. BOX 828, BLOOMFIELD HILLS, MI, 48303, US

(73) Assignee: DENSO CORPORATION, Kariya-city (JP)

(21) Appl. No.: 12/660,824

(22) Filed: Mar. 4, 2010

(30) Foreign Application Priority Data
Mar. 9, 2009 (JP) 2009-055533

(51) Int. Cl. H05K 1/18; H05K 3/10; H05K 3/40; H05K 3/46

(52) U.S. Cl. 361/783; 29/846; 29/832; 29/852

(57) ABSTRACT

A printed IC board has a multilayer printed wiring board and one or more bare IC chips. The multilayer printed wiring board has insulation layers made of PTFE, and wiring patterns formed on the insulation layers which are stacked to make a lamination structure. Electrode parts as parts of the wiring patterns are electrically connected to the bare IC chip. A copper member which serves as a reinforcing member is laid in a region formed in the insulation layers other than a first insulation layer. the region is formed directly below the electrode parts. The region is formed in a direction Z along a thickness of the stacked insulation layers. The region formed directly below the electrode parts in the insulation layers in the insulation layers other than the first insulation layer has a higher rigidity than the insulation layers.

### CROSS-REFERENCE TO RELATED APPLICATION

This application is related to and claims priority from Japanese Patent Application No. 2009-55533 filed on Mar. 9, 2009, the contents of which are hereby incorporated by reference.

### BACKGROUND OF THE INVENTION

1. Field of the Invention

The present invention relates to a printed wiring board, a printed integrated circuit (IC) board (or a printed IC assembly) composed of one or more bare IC chips and the printed wiring board having insulation layers and printed wiring patterns, and a method of manufacturing the printed wiring board and the printed IC board.

2. Description of the Related Art

Various types of a printed IC board (or printed IC assembly) composed of a printed wiring board are well known. For example, a printed wiring board has an insulation layer and a printed wiring pattern made of conductive wires such as copper wires. The insulation layer is made of insulation material which is selected according to its application. The printed IC board is comprised of a printed wiring board and a plurality of bare IC chips made of semiconductor such as silicon arranged on the printed wiring board.

In general, a step of manufacturing a printed IC board uses wire bonding or flip chip bonding method. In the wire bonding method, pad parts of a bare IC chip and electrode parts of a wiring pattern are electrically connected with conductive wires. On the other hand, in the flip chip bonding method, bond pad parts are electrically connected to bump parts (such as solder bumps) in order to bond an IC chip on a printed wiring board.

In the manufacturing of the printed IC board, the printed wiring board is placed on a heat-stage unit (which is made of ceramics or metal, for example) which is heated at a high temperature within a range of 150° C. to 200° C., and a bare IC chip is bonded onto the printed wiring board using conductive wires or solder bumps (hereinafter, such conductive wires and solder bumps will be referred to as the “bonding member”) when the bonding member is made of gold, by thermo compression bonding using ultrasonic vibration as an ultrasonic thermo compression bonding.

Further, an insulation material such as glass epoxy resin or paper phenol is generally used during the manufacturing of a printed IC board. However, in the manufacturing of such a printed IC board applicable to high frequency signals in a millimeter band or a millimeter wave, fluorocarbon polymers such as poly-tetra-fluoro-ethylene (PTFE) having a low dissipation factor, when compared with that of the above insulation material, is often used. For example, Japanese patent laid open publication No. JP H07-323501 discloses the conventional technique to use such PTFE. That is, using the insulation material of a low dielectric dissipation factor can suppress energy loss (dielectric loss) which is in proportion to a signal frequency and a dielectric dissipation factor.

By the way, it is known that an elastic modulus of insulation materials such as fluorocarbon resin and liquid crystal polymer (LCP), applicable to high frequency applications, is extremely decreased at a high temperature within a range of 150 to 200° C.

This decreases the reliability of the printed IC board because the insulation material contained in the printed wiring board placed on the heat stage unit disperses ultrasonic waves and distributes a load which is applied to the bonding member (such as a conductive wire and a solder bump), and this prevents an suitable bonding between a bare IC chip and bump parts (such as solder bumps).

### SUMMARY OF THE INVENTION

It is an object of the present invention to provide a printed wiring board, a printed integrated circuit (IC) board (or a printed IC assembly) composed of one or more bare IC chips and the printed wiring board on which those bare IC chips are placed and connected to a wiring pattern. The present invention also provides a method of manufacturing the printed wiring board and the printed IC board.

To achieve the above purposes, the present invention provides a printed IC board having printed wiring boards and one or more bare IC chips which are electrically connected. The printed wiring board is composed of an insulation layer made of insulation material on which the wiring pattern is formed. The wiring patterns have electrode parts through which the bare IC chip is electrically connected to the wiring patterns.

In particular, the printed IC board according to the present invention has an improved structure in which a reinforcing member is laid in the insulation layers, and the reinforcing member is laid in a region, which is formed in the insulation layers, directly below the position of the electrode parts in the wiring patterns. That is, the region is formed in the insulation layers directly below the electrode parts. The “region formed in the insulation layers directly below the electrode parts” indicates a predetermined region formed in the insulation layers directly below the electrode parts in a direction of Z axis (as the direction of a thickness of the insulation layers stacked in the printed IC board) observed from the electrode parts of the wiring pattern formed in a first insulation layer.

Because the region formed in the insulation layers, which is formed directly below the electrode parts on the printed IC board, has an increased rigidity by the presence of the reinforced member, this makes it possible to easily propagate or transmit ultrasonic waves and a load in the Z axis (or toward the direction of the thickness of the insulation layer), where the ultrasonic waves and the load are applied to the printed wiring board side during the step of electrically connecting the bare IC chip to the wiring patterns through connection members such as conductive wires or vamps during the manufacture of the printed IC board.

That is, the present invention provides the printed IC board which selects in advance and then uses the reinforcing member in the insulation layer, the rigidity of which is higher than that of the insulation material forming the insulation layer, regardless of a type of the insulation material forming the insulation layer. This structure can properly perform the thermal-fused step in order to connect the connection material such as conductive wires and bumps to the electrode parts of the wiring pattern formed on the surface of the insulation layer. The above structure allows one or more bare IC chips to be bonded to the printed circuit board in the printed IC board.

In accordance with another aspect of the present invention, there is provided a printed wiring board having a structure in which a wiring pattern is formed on an insulation layer made of insulation material, electrode parts are formed on the wiring pattern, which electrically connect the wiring pattern to a bare IC chip. In this structure of the printed wiring pattern, a reinforcing member having a predetermined rigidity, which is higher than that of the insulation material, is laid in a region formed in insulation layers. The position of the region corresponds to the electrode parts formed on the insulation layer. This region is formed directly below the electrode parts in insulation layers other than the insulation layer on which the electrode parts are formed. It is therefore possible to suitably apply the printed wiring board to the printed IC board according to the present invention.

In accordance with another aspect of the present invention, there is provided a method of manufacturing the printed IC board previously described. This printed IC board is comprised of the multilayer printed wiring board and one or more bare IC chips placed on the multilayer printed wiring board. The multilayer printed wiring board is comprised of a plurality of the insulation layers and the wiring patterns formed on the insulation layers, and the insulation layers and the wiring patterns are stacked to make a lamination structure. In particular, the method of the present invention has a step of forming a penetration hole as a region in the insulation layers other than a first insulation layer, which is directly below the electrode part. The electrode parts are formed on a surface of the first insulation layer, and the electrode parts are electrically connected to the bare IC chip, the first insulation layer is stacked on a second insulation layer so that a surface of the first insulation layer, which is opposite to the surface on which the electrode parts are formed, faces a surface of the second insulation layer. The method further has a step of inserting the reinforcing member having a predetermined rigidity, which is higher than that of the insulation material, into the penetration hole. The method further has a step of stacking a plurality of the insulation layers.

Specifically, in the first step, the penetration hole is formed in the insulation layers other than the first insulation layer. The penetration hole is formed in the insulation layers other than the first insulation layer, which is directly below the electrode part in the wiring pattern formed on the first insulation layer. In the following step, the reinforcing member is inserted into the penetration hole, which is higher in rigidity than the insulation material forming the insulation layers. In the following step, the first insulation layer and the group of the insulation layers other than the first insulation layer are stacked together in order to make the printed IC board having a lamination structure.

According to the method of manufacturing the printed IC board, it is possible to easily lay the reinforcing member into the insulation layers, and to properly connect the bare IC chip to the multilayer printed wiring board.

### BRIEF DESCRIPTION OF THE DRAWINGS

A preferred, non-limiting embodiment of the present invention will be described by way of example with reference to the accompanying drawings, in which:

FIG. 1 is a view showing a configuration of a printed IC board according to a first embodiment of the present invention;

FIG. 2A to FIG. 2H are views showing main steps of manufacturing the printed IC board according to the first embodiment of the present invention;

FIG. 3A to FIG. 3C are views showing a configuration of a printed IC board according to a second embodiment of the present invention;

FIG. 4A to FIG. 4E are views showing main steps of manufacturing the printed IC board according to the second embodiment of the present invention;

FIG. 5 is a view showing a configuration of a printed IC board according to a third embodiment of the present invention;

FIG. 6A to FIG. 6G are views showing main steps of manufacturing the printed IC board according to the third embodiment of the present invention; and

FIG. 7A to FIG. 7C are views showing a configuration of a printed IC board according to another embodiment of the present invention.

### DETAILED DESCRIPTION OF THE PREFERRED EMBODIMENTS

Hereinafter, various embodiments of the present invention will be described with reference to the accompanying drawings. In the following description of the various embodiments, like reference characters or numerals designate like or equivalent component parts throughout the several diagrams.

### First Embodiment

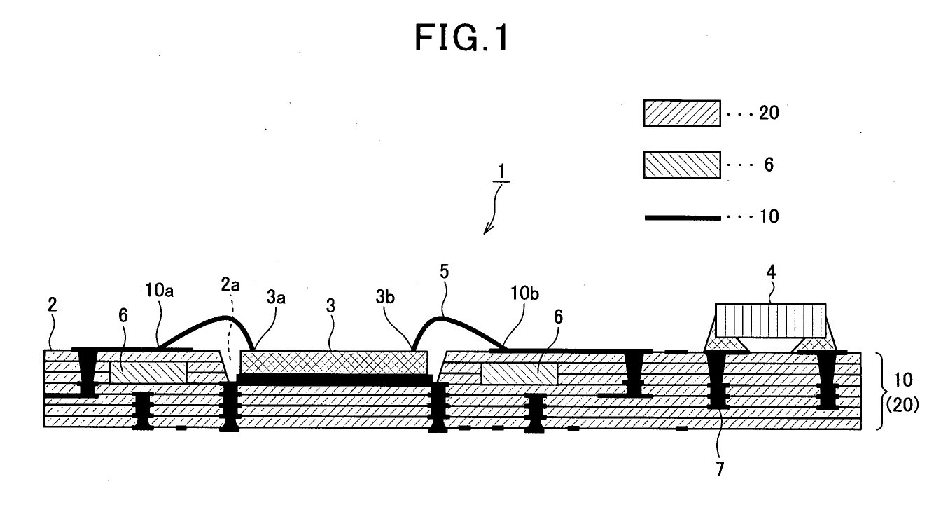

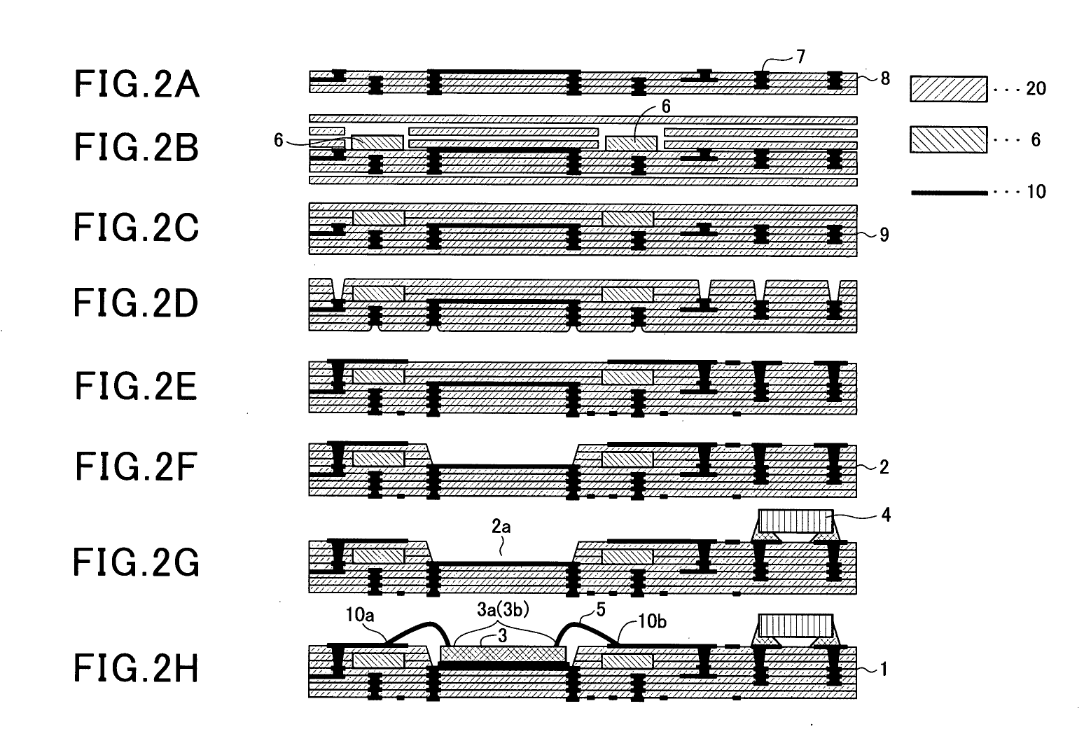

A description will be given of a printed IC board (or a printed IC assembly) according to the first embodiment of the present invention with reference to FIG. 1 to FIGS. 2A-2H.

FIG. 1 is a view showing a configuration of the printed IC board 1 according to the first embodiment of the present invention. FIG. 2A to FIG. 2H are views showing main steps of manufacturing the printed IC board 1 according to the first embodiment of the present invention.

### <Entire Structure>

As shown in FIG. 1, the printed IC board 1 is composed mainly of a multilayer printed wiring board 2, one or more bare IC chips 3 (by the way, FIG. 1 only shows a single bare IC chip 3 for brevity), and chip components 4 such as capacitances and resistances. The multilayer printed wiring board 2 has a multilayered structure in which a plurality of printed wiring patterns is stacked to make a lamination structure, where the printed wiring pattern is made of a copper thin film. The bare IC chip 3 is made of semiconductor such as silicon. In particular, the bare IC chip 3 and the chip components 4 are mounted on the surface of the multilayer printed wiring board 2.

The bare IC chip and the surface of the multilayer printed wiring board 2 are electrically connected together by using conductive wires 5 made of gold or copper. It is also acceptable for the chip components 4 to be built in the multilayer printed wiring board 2.

The bare IC chip 3 is a semiconductor IC element which is not packaged. That is, the bare IC chip 4 is laid on and fixed to a cavity part 2a formed on the surface of the multilayer printed wiring board 2 by using adhesive such as Ag epoxy resin or silicon resin. The conductive wire 5 is electrically connected to pad parts 3a and 3b on the bare IC chip 3 by wire bonding.

The multilayer printed wiring board 2 is comprised of a plurality of the insulation layers 20 made of insulation material and the wiring pattern 10. In the wiring pattern 10, a plurality of parts 10a and 10b (hereinafter, referred to as the “electrode parts”) are formed on signal lines. Those electrode parts 10a and 10b are electrically connected to the conductive wires 5 by wire bonding.

The insulation layers 20 are composed of a group of insulation layers which are stacked to form the multilayer printed wiring board 2. As shown in FIG. 1, in the structure of the insulation layers 20 having N layers (N=1 to 7 in the first embodiment shown in FIG. 1), a copper member 6 having a high rigidity (serving as a “reinforcing member”) is laid in a predetermined region (which corresponds to the “region directly below the electrode parts 10a and 10b”) that corresponds to a second layer (N=2) and a third layer (N=3) counted from the electrode parts 10a and 10b side.

Such a predetermined part is formed in the insulation layers 20 in the multilayer printed wiring board 2 every the electrode parts 10a and 10b. Further, vias 7 are formed to connect signal lines together or connect grounded lines together, which are formed between the different insulation layers 20.

### <Method a of Manufacturing Printed Ic Board>

Next, a description will now be given of the method A of manufacturing the printed IC board 1 according to the first embodiment of the present invention.

As shown in FIG. 2A to FIG. 2H, the method A of manufacturing the printed IC board 1 uses a sequential lamination method to produce a compressed substrate 9. In the method, a base substrate 8 is formed by stacking a plurality of the insulation layers 20 and the wiring pattern 10. Then, the insulation layer 20 and the copper member 6 are further stacked on the base substrate 8. The stacking step is repeated in order to produce the pressed substrate 9

In step to produce the base substrate 8 shown in FIG. 2A, a penetration hole is formed in a pre-impregnated layer by a laser device, et al., and the penetration hole is then filled with a conductive paste in order to make the pre-impregnated layer with a via 7 (which corresponds to the insulation layer 20). A copper thin film is adhered to both surfaces of the pre-impregnated layer with the via 7 by a thermal pressing using a lamination press or a roll laminator. A wiring pattern 10 is formed on the copper thin film adhered to the insulation layer 20 by etching. Finally, the insulation layer 20 on which the wiring pattern 10 is formed is placed between two pre-impregnated layers and a pair of copper thin films, and those layers are adhered and fixed together to make a lamination structure by a thermal pressing so that the wiring pattern 10 is formed between both the surfaces of the lamination. This produces the base substrate 8 comprised of the three insulation layers 20 and the four-layer wiring patterns 10.

The concept of the present invention is not limited by the above method of producing the base substrate 8. For example, it is possible to use another method of producing the base substrate 8, in which a wiring pattern is formed on one surface of each of plates by etching, onto which a copper thin film is adhered, and vias 7 are then filled. Finally, those plates having the wiring pattern and the vias 7 are stacked and simultaneously compressed together.

It is also possible to use another built-up method in order to produce the base substrate 8. In addition, it is possible for the base substrate 8 to have another structure composed of a plurality of insulation layers 20 and the wiring pattern 10 other than the structure composed of the three layer insulation layers 20 and the four layer wiring pattern 10.

Next, as shown in FIG. 2B and FIG. 2C, two cavities are formed in the two pre-impregnated layers (which correspond to the two insulation layers 20) by a laser device, et al., and copper members are inserted in those cavities. Finally, the seven insulation layers 20 are laminated and strongly adhered by a thermal pressing so that the two insulation layers 20 with the two cavities into which the copper members are inserted and laid become the second and third layers, the three insulation layers forming the base substrate 8 become the fourth to sixth layers, and the two insulation layers 20 become the first and seventh layer. That is, the second to sixth insulation layers 20 are sandwiched by the first and seventh insulation layers 20.

Next, as shown in FIG. 2D, FIG. 2E, FIG. 2F, via holes are formed at predetermined positions in the first to third insulation layers of the pressed substrate 9 by using a laser device, etc. The via holes are then filled with a conductive paste so that the conductive paste is electrically contacted with the vias 7 at the predetermined positions laid in the base material 8. Further, the wiring pattern is formed at both the surfaces of pressed substrate 9. A cavity part 2a is formed at the predetermined position in the first to third layers of the multilayer printed wiring board 2 by a laser device, et al., in order to produce the multilayer printed wiring board 2 composed of the seven insulation layers 20 and the six wiring pattern 10.

Finally, as shown in FIG. 2G and FIG. 2H, one or more bare IC chips 3 are placed in and die-bonded to the cavity part 2a by adhesive such as Ag epoxy resin or silicon resin. The chip components 4 such as capacitances and resistances are also bonded on the predetermined positions of the signal lines and the ground formed on the surface of the multilayer printed wiring board 2 by soldering. The multilayer printed wiring board 2 with the bare IC chip 3 is placed on the heat stage unit which is heated at a temperature within a range of 150° C. to 200° C. The pad parts of the bare IC chip 3 are electrically connected to the electrode parts 10a and 10b formed on the surface (at the first insulation layer 20 side) of the multilayer printed wiring board 2 by using the conductive wires 5 made of gold or copper.

### <Effects>

The method A of producing the printed IC board 1 can properly bond the conductive wires 5 to the electrode parts 10a and 10b by a thermal fusing because no ultrasonic wave is dispersed and no load is distributed by the presence of the copper member 6 formed directly below the insulation layer 20 even if ultrasonic waves and load are applied to the multilayer printed wiring board 2 when the pad parts of the bare IC chip 3 are electrically connected to the electrode parts 10a and 10b formed on the surface of the multilayer printed wiring board 2 by wire bonding connection.

Accordingly, because the printed IC board 1 produced by the method according to the first embodiment has an improved structure in which the bare IC chip 3 is properly connected to the multilayer printed wiring board 2, the printed IC board 1 has a high reliability in structure and operation.

In addition, it is possible to prevent the wiring pattern 10 from being separated from the insulation layer 20, as an additional effect of preventing the insulation layer 20 from being separated from the copper member 6 because the copper member 6 (serving as the reinforcing member) and the wiring pattern 10 are made of same material so that the copper member 6, and the wiring pattern 10 have the same linear expansion coefficient.

### Second Embodiment

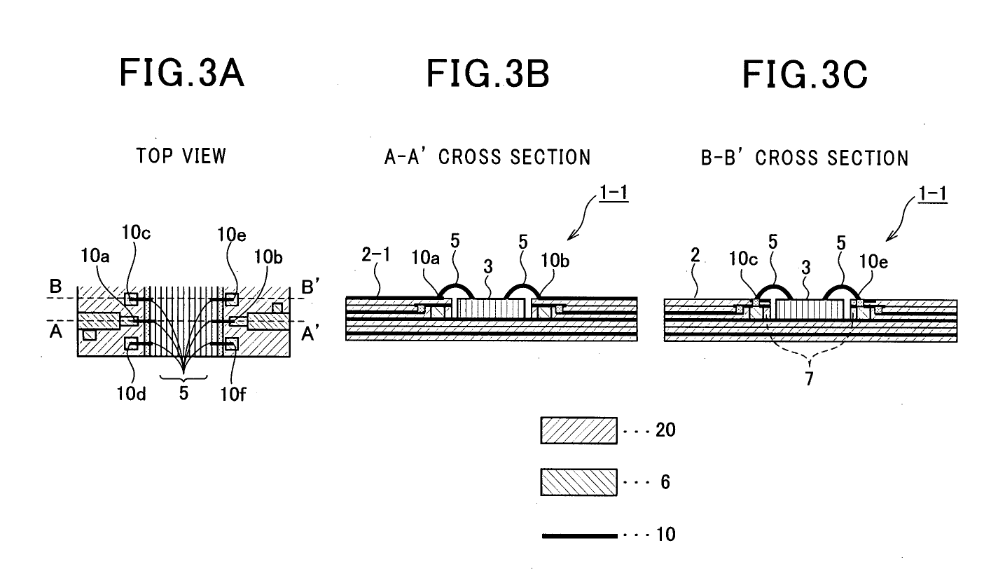

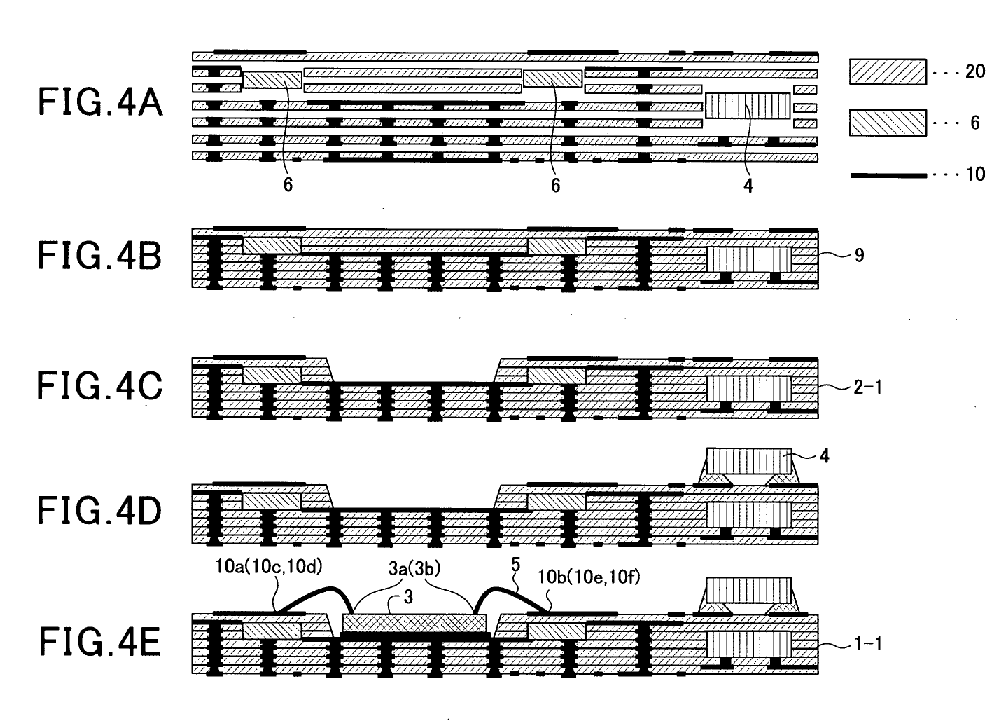

A description will be given of the printed IC board 1-1 according to the second embodiment of the present invention with reference to FIGS. 3A to 3C, and FIGS. 4A to 4E.

FIG. 3A, FIG. 3B, and FIG. 3C are views showing a configuration of the printed IC board 1-1 according to the second embodiment of the present invention. FIG. 4A to FIG. 4E are views showing main steps of producing the printed IC board 1-1 according to the second embodiment of the present invention.

### <Entire Structure>

As shown in FIG. 3A, FIG. 3B, and FIG. 3C, the printed IC board 1-1 has a multilayer printed wiring board 2-1 which is different in structure from the multilayer printed wiring board 2 in the printed IC board 1 according to the first embodiment. The following description will explain different components from the components of the printed IC board 1 according to the first embodiment, and not explain the same components between the first and second embodiments for brevity.

The multilayer printed wiring board 2-1 has a plurality of pre-impregnated layers 20 (which correspond to the insulation layers 20) which are formed by impregnating poly-tetra-fluoro-ethylene (PTFE) having a low dissipation factor into glass cloth (which serves as a “filler” or a “supplementing material”). In the multilayer printed wiring board 2-1, wiring pattern 10 is formed on a plurality of the insulation layers 20. The glass cloth is contained in the insulation layer 20 by a ratio according to the impregnation amount of PTFE so that the insulation layer 20 and the wiring pattern 10 have a same linear expansion coefficient.

The electrodes 10a and 10b are formed on the signal lines in the wiring pattern 10, and the ground pads 10c, 10d, 10e, and 10f are further formed on the wiring pattern 10. That is, in the structure of the printed IC board 1-1 according to the second embodiment, the electrodes 10a and 10b and the ground pads 10c, 10d, 10e, and 10f correspond to the electrode parts.

### <Method B of Producing the Printed Ic Board 1-1>

Next, a description will now be given of main steps of the method B of manufacturing the printed IC board 1-1 according to the second embodiment of the present invention.

The method B according to the second embodiment is different from the method A according to the first embodiment mainly in the step of producing the pressed substrate 9. The following description will explain the different steps for brevity. That is, the second embodiment has the different step of laying the bare IC chip 4 and other components during the production of the pressed substrate 9 when compared with that of the method A of the first embodiment. The following description will explain only the different steps, and omit the same steps between the methods A and B.

In the method B of producing the printed IC board 1-1 according to the second embodiment, as shown in FIG. 4A to FIG. 4E, the seven insulation layers 20 and the eight-layer wiring patterns 10 are laminated simultaneously by a single laminating step.

Specifically, as shown in FIG. 4A and FIG. 4B, a first cavity is formed in the second insulation layer 20 and the third insulation layer 20, and second cavity is formed in the third insulation layer 20, the fourth insulation layer 20, and the fifth insulation layer 20 by using a laser device, et al.

A copper member 6 (which serves as the reinforcing member) is then placed in the first cavity and a chip component 4 is placed in the second. The seven insulation layers 20 in which the wiring patterns 10 are formed are stacked and thermally pressed to produce a lamination structure. Vias 7 are formed in parts in the sixth insulation layer 20, which correspond to the implementation positions for the chip component 4 such as capacitances and resistances. Through these vias 7 the chip component 4 is electrically connected.

### <Effects>

As described above in detail, according to the printed IC board 1-1 of the second embodiment, because the PTFE is used in each of the insulation layer 20 and such a PTFE has a small (or low) dielectric dissipation factor, it is possible to suppress dielectric loss energy loss (dielectric loss) dielectric dissipation factor. Therefore it is possible to suitably apply the printed IC board 1-1 according to the present invention to devices which use high frequency signals in a millimeter band or a millimeter wave.

Further, according to the printed IC board 1-1 of the second embodiment, because the PTFE contains glass cloth so that the insulation layers 20 and the wiring pattern 10 have the same linear expansion coefficient, this can prevent the wiring pattern 10 from being separated from the insulation layers 20.

### Third Embodiment

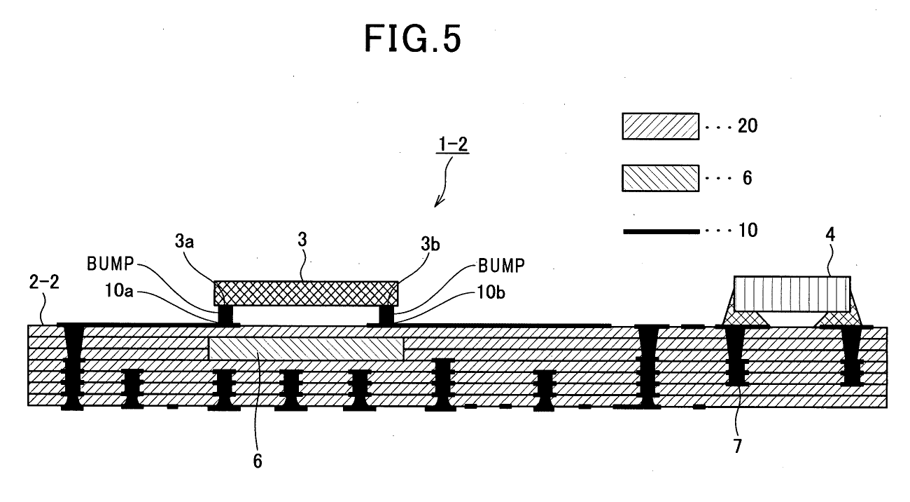

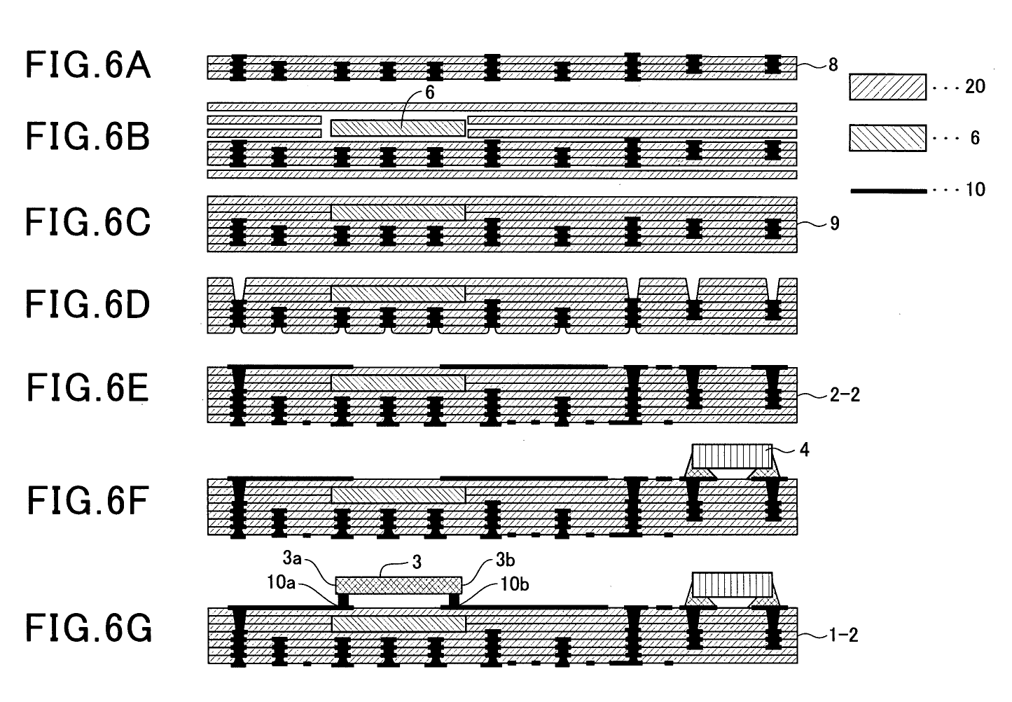

A description will be given of the printed IC board 1-2 according to the third embodiment of the present invention with reference to FIG. 5 and FIGS. 6A to 6G.

FIG. 5 is a view showing a configuration of the printed IC board 1-2 according to the third embodiment of the present invention. FIG. 6A to FIG. 6G are views showing main steps of producing the printed IC board 1-2 according to the third embodiment of the present invention.

### <Entire Structure>

As shown in FIG. 5, the printed IC board 1-2 according to the third embodiment has a multilayer printed wiring board 2-2 which is different in structure from the multilayer printed wiring board 2 in the printed IC board 1 according to the first embodiment, and also from the multilayer printed wiring board 2-1 in the printed IC board 1-1 according to the second embodiment.

Because the printed IC board 1-2 according to the third embodiment is different in connection structure between the bare IC chip and the multilayer printed wiring board from the printed IC board 1 according to the first embodiment, the following description will mainly explain the different connection structure, and not explain the same components between the first to third embodiments for brevity.

Specifically, the printed IC board 1-2 according to the third embodiment is composed mainly of the multilayer printed wiring board 2-2, the bare IC chip 3, the chip components 4 such as capacitances and resistances. Further, the bare IC chip 3 and the electrode parts 10a and 10b formed on the surface of the multilayer printed wiring board 2-2 are electrically connected through bumps formed on the pad parts 3a and 3b of the bare IC chip 3. For example, the bumps are made of gold or copper.

Still further, the wiring patterns 10 are formed in the multilayer printed wiring board 2-2 by well-known coplanar lines, and the width of a signal line in the wiring pattern 10 is determined so that the characteristic impedance of the multilayer printed wiring board 2-2 has a predetermined value (for example, 50Ω) in consideration of a gap between the signal line and grounds which are formed on a same surface.

### <Method C of Manufacturing the Printed Ic Board 1-2>

As shown in FIG. 6A to FIG. 6G, the method C according to the third embodiment is different from the method A of the first embodiment as follows.

The method C of the third embodiment forms a single cavity in the step of producing the compressed substrate 9, and uses a flip chip bonding.

The description will explain the different steps, and omit the same steps between the first embodiment and the third embodiment for brevity.

As shown in FIG. 6B, and FIG. 6C, during the step of producing the compressed substrate 9, a single cavity is formed in the pre-impregnated layers (which corresponds to the three insulation layers 20) by a laser device, et al., and a copper member is inserted in the cavity. Finally, the seven insulation layers 20 are laminated and strongly adhered by a thermal pressing so that the two insulation layers 20 with the cavity, into which the copper members 6 (which serves as the reinforcing member) is inserted, become the second and third layers, the three insulation layers forming the base substrate 8 become the fourth to sixth layers, and the two insulation layers 20 become the first and seventh layer. That is, the second to sixth insulation layers 20 are sandwiched by the first and seventh insulation layers 20.

The copper member 6 has approximately a same area of the implementation area of the bare IC chip 3 and placed or laid in the area which faces the position to implement the bare IC chip 3.

In the steps shown in FIG. 6F and FIG. 6G, the chip components 4 such as capacitances, resistances, et al., are fixed at predetermined positions on the signal lines formed on the surface of the multilayer printed wiring board 2-2 by soldering. The multilayer printed wiring board 2-2 with the bare IC chip 3 is placed on the heat stage unit which is heated at a temperature within a range of 150° C. to 200° C. As shown in FIG. 6G, the bare IC chip 3 is placed face down on the surface of the first insulation layer 20 in order to directly and electrically connect bumps formed on the pad parts 3a and 3b of the bare IC chip 3 to the electrode parts 10a and 10b formed on the surface (at the first insulation layer 20 side) of the multilayer printed wiring board 2-2.

### <Effects>

According to the method C of producing the printed IC board 1-2 of the third embodiment, because the bare IC chip 3 is electrically connected to the multilayer printed wiring board 2-2 without using any conductive wire 5 (on the other hand, the methods A and B according to the first and second embodiments use the conductive wires 5), it is possible to decrease the implementation area of the bare IC chip 3 and suppress the total length of the connection part between the bare IC chip 3 and the multilayer printed wiring board 2-2 as small as possible, and this structure makes it possible to improve the electrical characteristics of the printed IC board 1-2.

### <Other Modifications>

The concept of the present invention is not limited by the first embodiment, the second embodiment, and the third embodiment previously described. It is possible to apply the concept of the present invention to various modifications within the scope of the present invention.

For example, because the first and second embodiments provide the wiring patterns 10 in the printed IC board formed by microstrip lines or coplanar lines (as a type of electrical transmission line), the present invention is not limited by this. It is possible to form the wiring patterns 10 by known ground coplanar line.

As one example of the wiring patterns 10 made of microstrip line, a line pattern is formed on the surface (as the primary surface) containing the electrode parts 10a and 10b in the first insulation layer 20, a ground pattern is formed at an area, which is required to lay the copper member 6 and the vias 7 in the region which is formed directly below the electrode parts, on the surface (as the secondary surface) between the first and second insulation layers 20. A ground pattern is formed on the surface (as the third surface) in the second insulation layer 20, which is the opposite surface to the surface of the first insulation layer 20. The ground patterns in the secondary surface and the third surface are electrically connected through the vias 7 formed in the second insulation layer 20.

The thickness “h” of the two insulation layers 20 can be expressed by the following equation (1):

Z=(120π/∈eff^{1/2})/{W/h+1.393+ln(W/h+1.444)} (1),

where ∈ eff^{1/2}=(∈r+1)/2+(∈r−1)/2(1+12 h/W)^{1/2}, W is a width of the microstrip line, ∈r is a relative static permittivity (or a static relative permittivity), and Z is a characteristic impedance of the multilayer printed wiring board. For example, because h becomes approximately 135 μm (h÷135 μm) when Z=50Ω, ∈r=3.5, W=300 μm, it is preferable for each of the insulation layers 20 to have the thickness of approximately 67.5 μm.

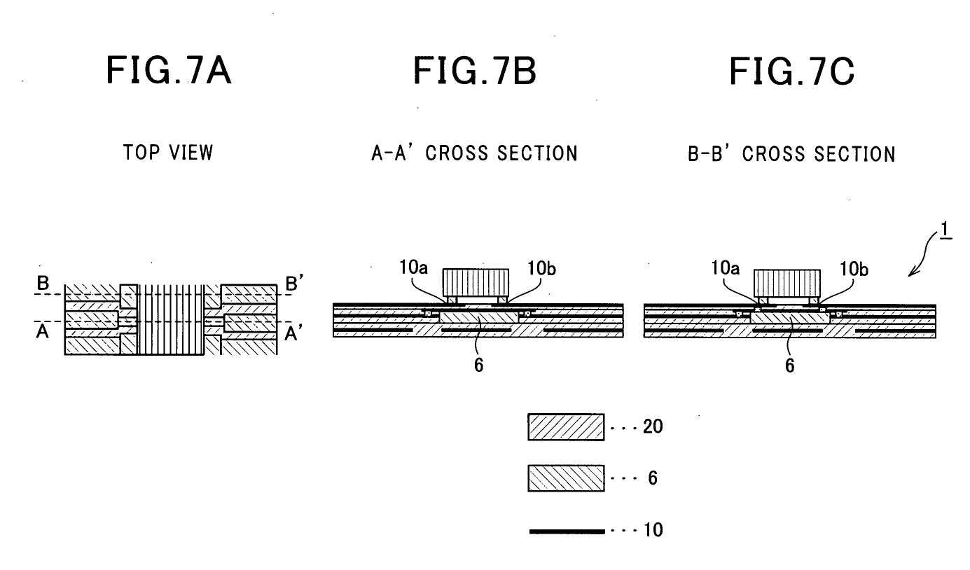

FIG. 7A to FIG. 7C are views showing the above configuration of the printed IC board according to another modification of the present invention.

The structure of the printed IC board shown in FIG. 7A, FIG. 7B, and FIG. 7C makes it possible to suppress ultrasonic waves from being dispersed and a load from being distributed applied to the electrode parts 10a and 10b during the step of manufacturing the printed IC board by decreasing the thickness of the region which is directly below the electrode parts 10a and 10b. This structure makes it possible to properly connect the bare IC chip 3 onto the multilayer printed wiring board. Still further, it is possible to suppress deterioration of a conductive loss of the signal line because the wiring has a optimum width by adequately keeping the thickness of the insulation layers 20 other than the region which is directly below the electrode parts 10a and 10b.

By the way, each of the printed IC boards according to the first to third embodiments and the modifications previously described shows the structure to mount the single bare IC chip 3 on the printed IC board. The present invention is not limited by this structure. It is possible to have a structure to mount a plurality of bare IC chips on the printed IC board. Still further, it is possible for the printed IC board to comprise a single layer printed wiring board instead of the multilayer printed wiring board.

### <Other Features and Effects of the Present Invention>

The printed IC board according to the present invention uses thermoplastic resin as the insulation material to form the insulation layer because fluorocarbon polymers such as PTFE, plastic resin such as PEEK (polyetheretherketone), and LCP (liquid crystal polymer) have a low dielectric dissipation factor when compared with insulation resin such as glass epoxy and phenol paper, and most insulation resin, suitable for stacking a plurality of printed wiring boards, have thermoplastic characteristics.

Because the printed IC board having the above structure can suppress energy loss (dielectric loss) in proportion to signal frequency and dielectric dissipation factor, it is possible to apply the printed IC board of the present invention to various devices using high frequency signals in a millimeter band or a millimeter wave.

In the printed IC board according to the present invention, the region which is formed directly below the electrode parts has an single region formed in the insulation layers so that this single region corresponds to the entire of the electrode parts. The present invention is not limited by the above structure. For example, a plurality of regions is formed directly below the electrode parts in the insulation layers.

Because the printed IC board having the above structure can decrease the ratio of occupying the reinforcing member in the insulation layers, it is possible to increase a density of the wiring pattern in the insulation layers when a plurality of wiring patterns is formed in the insulation layers or the wiring patterns are formed with microstrip line.

It is preferred to use a multilayer printed wiring board, as the printed wiring pattern, which has a structure to stack a plurality of insulation layers and wiring patterns in a lamination structure. Using such a multilayer printed wiring board can decrease the area of the printed wiring board in the printed IC board.

Specifically, it is preferable for the reinforcing member formed in the multilayer printed wiring board to have a structure in which the reinforcing member is formed in the insulation layers other than a first insulation layer, which are stacked, observed from the other surface of the first insulation layer which is opposite to the surface of the first insulation layer on which the electrode parts are formed.

As this structure does not require formation of the region (as a concave part) for the reinforcing member in the first insulation layer, it can avoid using of any technique to prevent the reinforcing member from contacting with the electrode part. For example, a penetration hole is formed as the region directly below the electrode parts in a plurality of the insulation layers (referred to as the “target insulation layers”) other than the first insulation layer, and the reinforcing member is inserted into and laid in the penetration hole. The target insulation layers having the penetration hole are sandwiched by the first insulation layer and the remaining insulation layer other than the target insulation layers in the multilayer printed wiring board. This can easily lay the reinforcing member in the penetration hole formed in the target insulation layers.

By the way, in order to suppress ultrasonic waves from dispersing and a load from being distributed during the step of manufacturing the printed IC board, it is desired to decrease the thickness of the insulation layer.

In order to achieve this, it is preferable for the first insulation layer to be smaller in thickness than each of other insulation layers.

In this case, decreasing the thickness of the first insulation layer can suppress ultrasonic waves from dispersing and an applied load from being distributed when the insulation layers are stacked and then thermally adhered to make the printed IC board having a lamination structure. This can properly connect the bare IC chip to the wiring patterns in the multilayer printed wiring board.

It is necessary to more decrease the width of such a signal line when the thickness of the insulation layer is more decreased when the wiring pattern is made of microstrip line in order to match impedance characteristics of the printed wiring board with a predetermined value (for example, 50 ω). However, excessively decreasing the width of the signal line would cause a conductive loss of the signal line and thereby cause increasing of the conductive loss of the entire circuit.

In order to avoid this, the present invention provides the printed IC board having the structure in which the plurality of the wiring patterns is formed with microstrip line which is a combination of line patterns and ground patterns, and the line pattern is formed on a first surface containing the electrode parts of the first insulation layer, the ground pattern is formed only in the region, which is directly below the electrode part, on a second surface of the first insulation layer which faces a surface of the second insulation layer, and the ground pattern is formed in a third surface of the second insulation layer which faces the second surface of the first insulation layer. Further, the ground patterns formed in the second surface and the third surface are electrically connected to vias formed in the second insulation layer.

The printed IC board having the above structure substantially decreases the thickness of the region in the first insulation layer, which corresponds to the region formed directly below the electrode parts, and thereby possible to properly connect the bare IC chip to the printed wiring boards, and suppress the conductive loss of the signal line without limiting the width of the signal line while keeping the thickness of the insulation layers other than the first insulation layer.

Further, it is preferable for the insulation material contains supplementing material to have a same linear expansion coefficient of the wiring patterns, and also preferable for the reinforcing member in the insulation layer to be made of a material having the same linear expansion coefficient of the wiring patterns.

It is sufficient for the supplementing material to contain an insulation material having a low linear expansion coefficient such as glass cloth, not required that both the entire of the insulation layers containing the supplementing material have the same linear expansion coefficient.

It is possible for the structure of the printed IC board to prevent the reinforcing member from being separated from the insulation layers, and the wiring patterns from being separated from the insulation layers.

While specific embodiments of the present invention have been described in detail, it will be appreciated by those skilled in the art that various modifications and alternatives to those details could be developed in light of the overall teachings of the disclosure. Accordingly, the particular arrangements disclosed are meant to be illustrative only and not limited to the scope of the present invention which is to be given the full breadth of the following claims and all equivalents thereof.

What is claimed is:

1. A printed IC board comprising:
a printed wiring board comprising an insulation layer made of insulation material on which a wiring pattern is formed; and
a bare IC chip electrically connected to the wiring pattern formed on the printed wiring board,
wherein electrode parts as a part of the wiring pattern are electrically connected to the bare IC chip, and a reinforcing member having a predetermined rigidity, which is higher than that of the insulation material forming the insulation layer, is formed in a region in the insulation layer, and directly below the electrode parts.

2. The printed IC board according to claim 1, wherein the insulation material is thermoplastic resin.

3. The printed IC board according to claim 2, wherein a plurality of regions are formed, corresponding to the electrode parts, in the insulation layer directly below the electrode parts.

4. The printed IC board according to claim 2, wherein the printed wiring board is a multilayer printed wiring board comprising a plurality of the insulation layers and wiring patterns which are stacked.

5. The printed IC board according to claim 4, wherein the reinforcing member is formed in the insulation layers other than a first insulation layer, and the electrode part is formed in the first insulation layer, and the first insulation layer is stacked on an surface of a second insulation layer, which is opposite to a surface of the first insulation layer on which the electrode part is formed.

6. The printed IC board according to claim 5, wherein a thickness of the first insulation layer is smaller than that of each of the other insulation layers in the multilayer printed wiring board

7. The printed IC board according to claim 5, wherein the wiring patterns are formed with microstrip line which is a combination of line patterns and ground patterns, and
the line patterns are formed on a first surface containing the electrode parts of the first insulation layer, the ground patterns are formed only in the region, which is formed directly below the electrode parts, on a second surface of the first insulation layer which faces a surface of the second insulation layer, and the ground patterns are formed in a third surface of the second insulation layer which faces the second surface of the first insulation layer, and
the ground patterns formed in the second surface and the third surface are electrically connected to vias formed in the second insulation layer.

8. The printed IC board according to claim 2, wherein the insulation material contains supplementing material in order to have a same linear expansion coefficient of the wiring patterns, and the reinforcing member has a material having the same linear expansion coefficient as the wiring patterns.

9. A printed wiring board in which a wiring pattern is formed on an insulation layer made of insulation material, electrode parts are formed on the wiring pattern, which electrically connect the wiring pattern to a bare IC chip, and a reinforcing member having a predetermined rigidity, which is higher than that of the insulation material, is laid in a region, corresponding to the electrode parts, and formed directly below insulation layers other than the insulation layer on which the electrode parts are formed.

10. A method of manufacturing a printed IC board which is comprised of a multilayer printed wiring board and a bare IC chip placed on the multilayer printed wiring board, where the multilayer printed wiring board is comprised of a plurality of insulation layers and wiring patterns formed on the insulation layers, and the insulation layers and the wiring patterns are stacked to make a lamination structure,
the method comprising steps of:
forming a penetration hole in a region directly below the electrode parts in the insulation layers other than a first insulation layer in the multilayer printed wiring board, where electrode parts are formed on a surface of a first insulation layer, and the electrode parts are electrically connected to the bare IC chip, the first insulation layer is stacked on a second insulation layer so that a surface of the first insulation layer, which is opposite to the surface on which the electrode parts are formed, faces a surface of the second insulation layer; and
inserting a reinforcing member having a predetermined rigidity, which is higher than that of the insulation material, into the penetration hole; and
stacking the plurality of the insulation layers.
